(19) United States
(12) Patent Application Publication
(10) Pub. No.: US 2009/0173371 A1
(43) Pub. Date: Jul. 9, 2009

(54) EUROPIUM-CONTAINING NANOPARTICLE MATERIALS USEFUL FOR SOLAR AND THERMAL ENERGY CONVERSION AND RELATED ISSUES

(75) Inventors: Brian A. Skoczenski, Portland, ME (US); Jun Feng, Frederick, CO (US); Guomin Shan, Carmel, IN (US)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: EDOTS Technology, LLC, Portland, ME (US)

(21) Appl. No.: 12/299,735

(22) PCT Filed: May 7, 2007
(86) PCT No.: PCT/US07/11012

§ 371 Date: Nov. 5, 2008

Related U.S. Application Data
(60) Provisional application No. 60/797,968, filed on May 5, 2006.

(51) Int. Cl. H01B 1/00; H01L 31/042; H01L 35/00; H01B 1/02

(52) U.S. Cl. 136/201; 136/259; 252/501.1; 252/512

(57) ABSTRACT

Collectors and storage material for solar or other light or heat energy conversion comprising a matrix of conductive material incorporating Europium-containing nanoparticles, and uses therefore are described and provided.

### CROSS-REFERENCE TO RELATED APPLICATIONS

This application is a U.S. National Stage of PCT/US07/11012, filed 7 May 2007, which claims the priority benefit of and incorporates by reference U.S. Provisional Patent Application No. 60/797,968 filed May 5, 2006, both of which are incorporated herein by reference in entirety.

### STATEMENT REGARDING FEDERALLY SPONSORED RESEARCH OR DEVELOPMENT

Not Applicable

### FIELD

The present invention relates in general to the field of energy generation, and in particular to novel solar and thermal energy collectors and their use.

### INTRODUCTION

Solar energy generation and photovoltaics offer an alternative to traditional fossil-fuel energy sources. In conventional solar cells, rays of sunlight are absorbed by semiconducting materials, such as silicon. While these have proven useful in certain contexts, their use has been limited by such factors as the limited efficiency of the conversion of solar radiation to electrical power output, the range of the electromagnetic spectrum convertible to solar-generated power, restrictions on the availability of solar radiation to generate power to sunny weather and locales, and the expense of the materials and/or manufacturing processes involved.

Steven McDonald et al. Nature Materials 4 Feb. 2005 www.nature.com/naturematerials describe a nanocomposite approach in which PbS nanocrystals tuned by the quantum size effect sensitize conjugated polymer poly[2-methoxy-5-(2′-ethylhexyloxy-p-phyenylenevinylene)] (MEH-PPV). They report that the device sensitizes the device into the infrared, and provides the potential advantages of ease of processing, low cost, physical flexibility and large area coverage provided by a polymer-based system, in contrast to conventional photovoltaics. However, the range and efficiency of the disclosed nanocomposites remain limited.

Independently, Europium-based nanocrystal particles have been developed with light-absorbing properties. See U.S. Pat. No. 6,783,699 B2 (2004). These materials are described as useful for biological assays where the phosphorescing nanoparticles serve to help detect biological or chemically-targeted substances.

### SUMMARY

The present teachings include collectors for solar and thermal energy conversion composed of materials incorporating Europium-containing nanoparticles for broad spectrum absorption of solar and thermal energy.

Accordingly, in one embodiment there is provided a collector for solar or other light or heat energy conversion to electrical energy. The collector includes a matrix of conductive materials incorporating Europium-containing nanoparticles. In further embodiments, the collector may include an aluminum oxide base crystal framework, an activator, an energy reservoir, and a co-activator.

In another aspect, a method for converting solar, other light or heat energy to electrical energy is provided. The method comprises exposing collectors as described above and hereinbelow to radiation for a time sufficient to convert said radiation to electrical energy.

In a further aspect, a method is provided for storing electrical energy. The method includes exposing a collector as described above and hereinbelow to radiation for a time sufficient to convert said radiation to electrical energy and retaining at least a portion of the converted energy until a time subsequent for which use of said energy is desired.

The present teachings include methods for using the solar/thermal collectors of the invention for conversion of solar power into electrical energy.

Solar and/or thermal collectors of the present invention provide broad-spectrum conversion to electrical energy by one or more of up-conversion, down-conversion of IR, visible and UV sources, as well as heat. Moreover, the properties of these collectors include enhanced efficiency of energy conversion, greater durability, improved physical flexibility, characteristically low impedance, longer emission half-life, and the ability to extend the range of use for solar conversion to include even cloudy and rainy weather conditions.

These and other features, aspects and advantages of the present teachings will become better understood with reference to the following description, examples and appended claims.

### DRAWINGS

Those of skill in the art will understand that the drawings, described below, are for illustrative purposes only. The drawings are not intended to limit the scope of the present teachings in any way.

FIG. 1 is a schematic of the preparation of a solar cell incorporating europium-containing nanoparticles.

FIG. 2 is a graph showing the up-conversion excitation and emission curve of green particles.

FIG. 3 is a graph showing the up-conversion excitation and emission curve of purple particles.

FIG. 4 is a graph showing down-conversion excitation and emission curve of green particles.

FIG. 5 is a graph showing down-conversion excitation and emission curve of purple particles.

FIGS. 6(a) and (b) are photographs illustrating light emission from particles due to friction-based heating.

FIGS. 7(a) and (b) are photographs illustrating light emission resulting from external application of heat.

FIG. 8 is a depiction of a solar collector composed of ITO glass and a green particle layer.

### DETAILED DESCRIPTION

### Abbreviations and Definitions

To facilitate understanding of the invention, a number of terms and abbreviations as used herein are defined below as follows:

As used herein, singular designations include the plural unless the context clearly dictates otherwise.

Up-conversion: As used herein, the term “up-conversion” refers to a process where light is emitted with photon energies higher than those of the light generating the excitation.

Down-conversion: As used herein, the term “down-conversion” refers to a process, such as produced by conventional fluorophores, where light is emitted with photon energies lower than those of the light generating the excitation.

Thermo-excitation: As used herein, the term “thermo-excitation” refers to the excitation of particles by heat (e.g., 100°-800° C.) to emit light.

Nanoparticle: As used herein, the term “nanoparticle” is broadly defined to include a particle, generally a semi-conductive or metallic particle, having a diameter in the range of about 1 nm to about 1000 nm, preferably in the range of about 1 nm to about 200 nm, more preferably in the range of about 10 nm to about 100 nm.

Europium-Containing Nanoparticle Materials Useful for Solar Energy Applications. Europium-containing nanoparticle compositions comprising an aluminum oxide crystal framework, europium (Eu) as an activator, a co-activator, and an energy reservoir, as described in U.S. Pat. No. 6,783,699 B2 Li et al. ('699 patent), U.S. Pat. No. 5,893,999 Tamatani et al. ('999 patent) and U.S. Pat No. 5,424,006 Murayama et al. ('006), possess fluorescing properties which have heretofore been utilized to label targeted biological or chemical compositions of interest. The varieties of Europium-containing nanoparticles and the methods provided for making them as described in the '699, '999 and '006 patents are fully incorporated herein by reference as discussed below. Applicants have discovered that materials incorporating these Eu-containing nanoparticles are especially suitable for use in solar energy conversion. By varying the exact composition, such nanoparticles may be produced which absorb a wide spectrum of energy. Thus, these materials are capable of capturing energy from infrared, visible and ultra-violet (UV) light, producing convertible energy through conventional down-conversion, but also, unexpectedly, by up-conversion. They also produce light emission and energy from thermo-excitation, thus providing a highly efficient broad-spectrum conversion of solar and other energy. Hence, materials comprising an appropriate mixture of different Eu-containing nanoparticles can be designed to absorb light wavelength covering much of the solar energy spectrum.

Preferred nanoparticles for solar energy applications include green-excitation wave-length in the range of about 270 nm-500 nm (peak at 440 nm) and about 800 nm-1050 nm (peak at 900 nm), with emission peaks at 510 and 540 nm; and purple-excitation wave-length in the range of about 250 nm-425 nm (peak at 340 nm) and about 650 nm-800 nm (peak at 770 nm), with emission peak at 440 nm. Mixtures of two or more different nanoparticles may be manufactured to provide a broader absorption spectrum. For example, a material comprising a green-purple mixture will absorb convertible energy at the wave-length range including 250-500 nm and 650-1050 nm.

As described in the '699 patent, the color of the light emitted by the nanoparticle may be adjusted based on the selection of the energy reservoir component. Use of strontium produces green-light emitting particles while incorporation of calcium into the aluminum-oxide framework will provide a purple-light emitting particle upon excitation. Other suitable materials for use as the energy reservoir include magnesium (Mg), and barium (Ba).

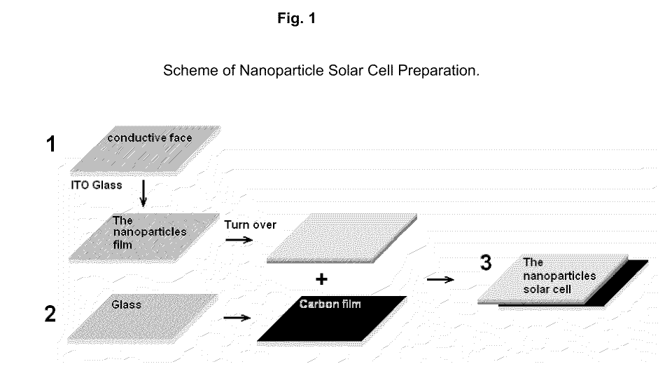

Collectors for converting solar energy to electrical energy may be produced by incorporating the nanoparticles of the invention into conductive or semi-conductive materials such as conductive glass; inherently conductive polymers, such as polyaniline, polythiophene, polyacetylene, polypyrrole polyanilenes, polyfluorenes, polynaphthalenes, poly(p-phenylene sulfides) poly(para-phenylene vinylenes), metal films, such as gold, silver, copper, platinum titanium, indium, tin thin film and its alloy materials, such as indium/tin; other semiconductor materials, such as TiO2, CdS, CdSe and carbon nanostructures, and a variety of semi-conductive ionic liquids; at a much lower cost and with greater durability than conventional solar collectors. These materials not only have low impedance but also are highly qualified for matching the Fermi level of the nanoparticles, which can be applied as photo anodes. Thus, any combination of the above materials providing contact with the nanoparticles, including but not limited to nanoparticles film spun or sprayed onto conductive substrates, nanoparticles mechanically embedded into conductive substrates or nanoparticles incorporated during polymerization of conductive polymers or production of carbon nanostructures. A schematic of the preparation of a nanoparticle-containing solar panel, using nanoparticle film, ITO film, and a carbon film backing, is depicted in FIG. 1.

Solar collectors made using nanoparticles according to the invention provide several specific functional characteristics:

Down-conversional behavior: they can be excited by light wavelengths (UV and visible) shorter than their emission photon wavelengths.

Up-conversional behavior: they can be excited by light wavelengths (infra-red and visible) longer than their emission photon wavelength.

Thermo-excitation: they can be excited by heat (such as 100°-300° C.) and emit light.

Long emission half-life: they can provide a half-life in the range of minutes or longer.

Common silicon-based solar cells have a band gap energy of 1.2 to 1.4 eV and only photons with the same or higher energy than the band gap energy have the potential to produce current. These photons are normally from the lower wavelength region of visible UV spectra. Thus, typically, only 15% or less of the solar energy can be utilized. However, Eu-containing nanoparticles incorporated into solar cells allow for a much wider range of photon energies (from infrared to UV) to be utilized. Accordingly, it is expected that the solar energy conversion will be much higher than for current silicon solar cells.

Required energy source: can be any light source, including light generated in sunny, cloudy, even rainy weather, as well as heat. See Example 11, below.

To applicants' knowledge, this ability of the materials and collectors of the invention to exhibit both down- and up-conversion properties is unique, providing the basis for solar collectors which are capable of being excited in a broad wavelength manner for both up-conversion and down-conversion potentialities.

Moreover, the nanoparticle-containing materials described herein may be used repeatedly without losing any of the properties mentioned above.

As exemplified infra, the nanoparticles may be incorporated into conductive or semi-conductive glass, plastic polymers, or other suitable materials to produce solar cells, such as conductive indium tin oxide (ITO) glass.

Energy Conversion Applications

The nanoparticle-enhanced solar collectors of the present invention can enjoy wide application not only for any area where current solar cell technology is applied but also open new areas of use. For example, solar panels may be incorporated into the surfaces of electric or hybrid vehicles. Arrays of solar cells may be used to power remote facilities not otherwise accessible by power grids. Solar power cells can be incorporated in clothing articles to provide power for communication or entertainment devices. Increased solar energy conversion efficiency may allow for smaller storage batteries and thereby decreasing the weight of, for instance, communication satellites. Additionally, the unexpectedly long half-life of the materials, excited state provides the opportunity for their use for extended energy storage, and for uses which require longer-term energy storage. See, e.g., Example 11, which illustrates the lengthy period for the sunlight-exposed collector to decay, once the direct exposure ended, to the “dark room level” current production. This property permits a leveling out of energy production in comparison to a conventional solar cell under conditions of rapidly changing light, such as occurs on a partly cloudy day. Low weight, flexible solar power cells may facilitate transport and deployment of electrical power generation capabilities to remote locations for recreational, research, disaster relief or national defense purposes. Lower cost of production and more efficient operation may allow incorporation into existing electric power generation and distribution grids. In addition, the thermal excitation properties of the enhanced collectors may allow alternative collector design to collect and utilize thermal energy. Another potential application is the use of these collectors to utilize strictly or principally thermal energy such as waste heat from industrial processes in a thermovoltaic manner to produce electrical power.

### EXAMPLES

Aspects of the present teachings may be further understood in light of the following examples, which should not be construed as limiting the scope of the present teachings in any way.

### Example 1

### Europium-Containing Fluorescent Nanoparticle Formation

5.14 g of Al₂O₃, was placed in a porcelain mortar. 7.18 g of Sr₂CO₃ salt was dissolved in ethanol and added to the Al₂O₃ powder. Then 0.089 g of Eu₂O₃, 0.084 g of La₂O₃, and 0.081 g of Nd₂O₃ were suspended in ethanol and added to the Al₂O₃ powder. The mixture was then blended and ground thoroughly with a porcelain pestle. After half drying while stirring, the particle mixture was placed in an environment of argon gas containing 1-2% hydrogen. Under a vacuum, the mixture was gradually heated at a rate of 50° C./hour until the temperature was 400° C. where it was held for 10 min. Then the temperature was raised to 800° C. Where it was held for 20 min, then to 1200° C. and held for 40 min, and then the temperature was increased to 1400° C., and allowed to remain at 1400° C. for 2-4 hours. The temperature was decreased to 200° C. at a rate of 50° C./hour and then the mixture was allowed to sit overnight.

### Example 2

### Europium-Containing Fluorescent Nanoparticle Formation

The nanoparticles were prepared as described in Example 1, however, 0.25 g of H.₃BO₃ was added to the mixture in order to decrease the reaction temperature. Using H₃.BO₃ can decrease the reaction temperature 200°-400° C. In this method, the mixture was heated to 1200° C. The resulting particles were suspended in ethanol after cooling and then washed with ethanol three times in order to remove the H₃BO₃. X-ray diffraction analysis of the particles clearly indicates that boron, either in elemental form, as an oxide, or as an acid is not present in the final particle.

### Example 3

### Preparation of Europium-Containing Nanoparticle Embedded Glass

An europium nanoparticle suspension was prepared in an alcoholic solution. TA glass surface, made conductive by coating with indium tin oxide, was covered with the suspension and placed in a vacuum hood for 2 hours. The glass was then heated in an oven to 800-1000° C. for 2-4 hours. The resulting product was nanoparticle conductive glass.

### Example 4

### Preparation of Europium-Containing Nanoparticle Embedded Conductive Polymer

A nanoparticle-embedded conductive polymer is prepared according to the polymerization method described in Li, Z. F.; Swilhart, M. T.; and Ruckenstein. (2004) The particles are first treated with (3-bromopropyl)trichlorosilane solution to generate capped particles. The particles are then placed in aniline overnight and subsequently washed with methanol. The particles are suspended in 1M HCl solution with 0.1M aniline and 0.1M (NH₄).₂S₂O₂/1M HCl solution is added. The mixture is allowed to polymerize in an ultrasonic bath for 30 minutes. The resulting polymers are washed with 0.1M NaOH followed by distilled water. (Li, Z. F.; Swilhart, M. T.; and Ruckenstein, 2004. Luminescent silicon nanoparticles are capped by conductive polyaniline through the self-assembly method. Langmuir 20, 1963-1971.).

### Example 5

### Construction of Nanoparticle Solar Cells

The europium-containing nanoparticles were suspended in butanol using a mortar and pestle and spread on the surface of ITO conductive glass. The glass was briefly dried in a hood under vacuum at room temperature for 20 minutes. The particles were annealed by placing the glass on a hot plate set to high, heated for 20-30 minutes, and allowed to cool slowly. Using a graphite rod (carbon), a carbon film was applied on one surface of a second piece of ITO conductive glass. This was then placed on the particle side of the first piece of ITO glass. Clips or tape were used to stabilize the glass as the solar cell was formed. (see FIG. 1)

### Example 6

### Up-Conversion of Nanoparticles

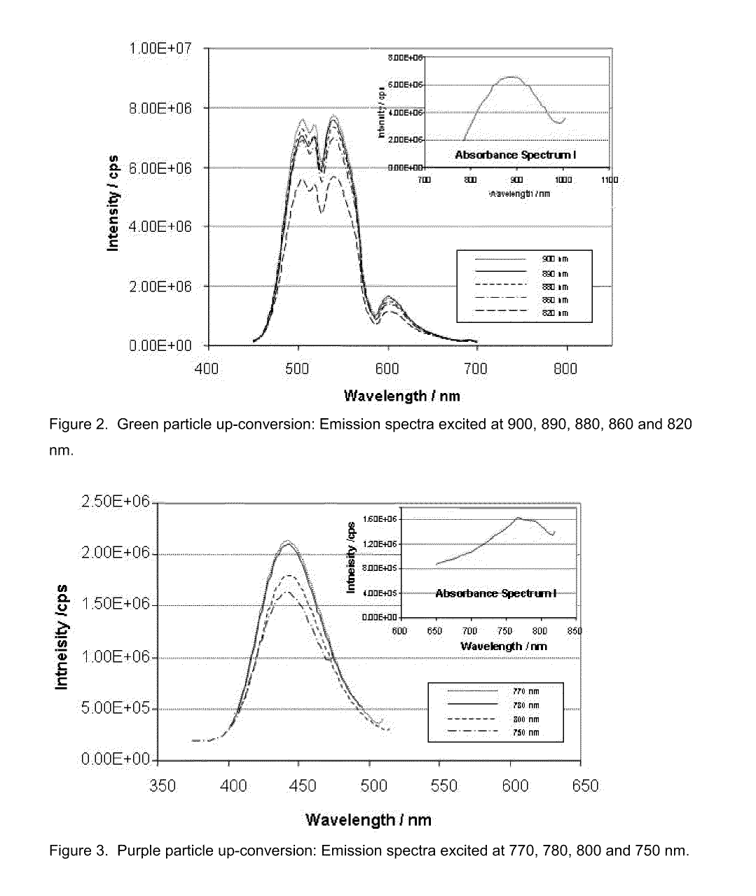

Europium-containing nanoparticles may be excited by long wavelength light such as near-infrared or infrared and emit a shorter wavelength light. To illustrate the up-conversion potential of these particles, green particles were excited at 820-900 nm using alternatively, a near-IR excitation source, a Xenon lamp with filters, and sunlight with filters and emitted green light with a peak at 540 nm. In an additional illustration, the green particles were placed in a container in a Fluoromax-3 spectrofluorometer (Instruments S.A., Inc., Edison, N.J.) and excited at 820, 840, 860, 880, 890 and 900 nm. The emission spectra were recorded from 450 to 700 nm with a peak at 540 nm. Similarly, purple particles were excited at 750, 770, 780 and 800 nm. The emission spectra were recorded from 370 to 520 nm with a peak at 442 nm. The up-conversion excitation and emission curves for the green and purple particles are depicted in FIGS. 2 and 3.

### Example 7

### Down-Conversion of Nanoparticles

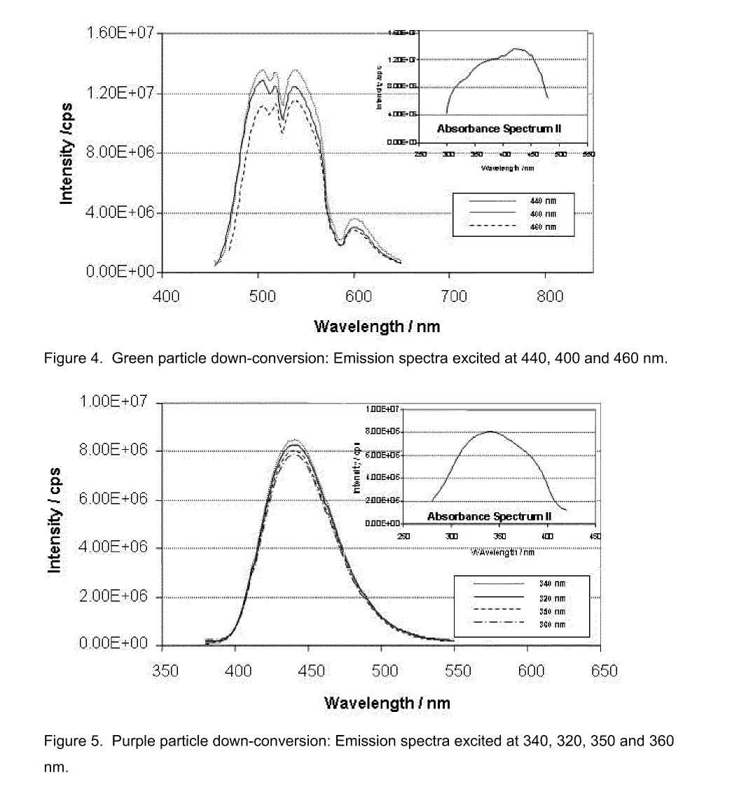

Like normal fluorophores, europium-containing nanoparticles according to the invention can be excited by short wave length light such as UV or visible light and emit a longer wave length light. To illustrate the down-conversion potential of these particles, green particles were excited at 300-500 nm using a UV/visible light source and emitted green light which peaked at 540 nm. In an additional illustration, the green particles were placed in a container in a Fluoromax-3 spectrofluorometer (Instruments S.A., Inc., Edison, N.J.) and excited at 400, 440, 450 and 460 nm. The emission spectra were recorded from 440 to 700 nm with a peak at 540 nm. Similarly, the purple particles were excited at 320, 340, 350 and 360 nm. Emission spectra were recorded from 370 to 520 nm. The down-conversion excitation and emission curves for the Green and Purple particles are depicted in FIGS. 4 and 5.

### Example 8

### Thermo-Excitation of Nanoparticles

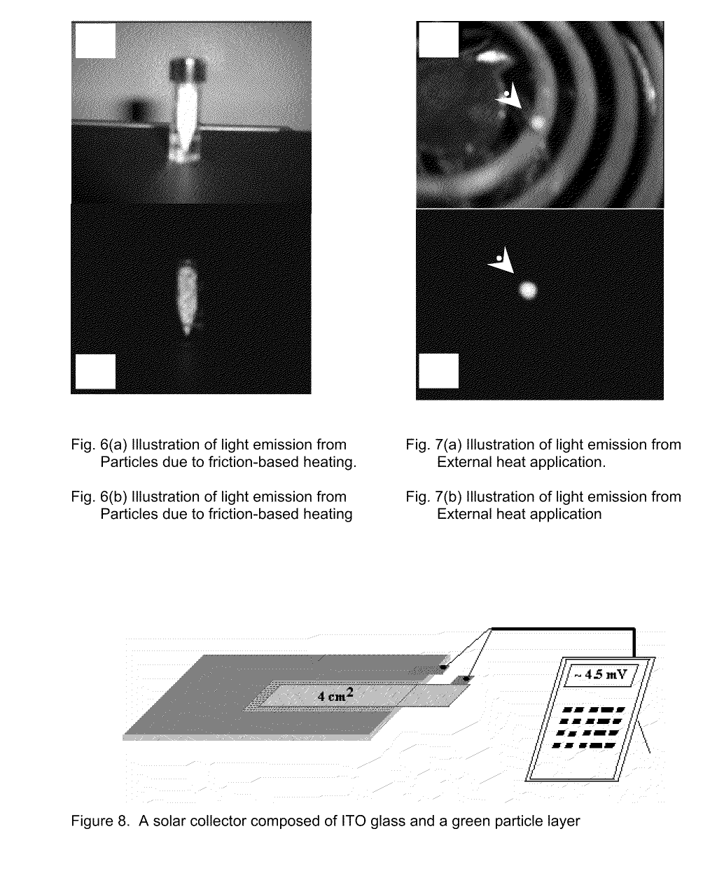

Europium-containing nanoparticles can be excited by thermal energy. To illustrate this principle, green particles were mechanically shaken vigorously in the dark creating friction-based heating, and emitted light. See FIGS. 6(a) and (b). In an additional illustration, the green particles were heated by application of an external heat source. When heated in the absence of light to approximately 100°-800° C., the particles emitted light. See FIGS. 7(a) and (b).

### Example 9

### Nanoparticles Retain Conversion Properties With Repeated Use

Europium-containing nanoparticles according to the invention can be repeatedly excited by short wavelength light such as UV or visible light and emit light at a longer wavelength. To illustrate the repeated use of these particles, the green particles, after use as described in Example 7 were stored under dark conditions for 2 hours and were then excited at 300 to 500 nm using a UV/visible light source or Xenon lamp with filters for 2-3 minutes. A green light was emitted with a peak at 540 nm.

### Example 10

### Generation and Measurement of Nanoparticle Material Photocurrent

The generation of photocurrent was demonstrated by obtaining photocurrent measurements using a solar cell as described in [0051]. The contribution of the material on conductivity was performed at a certain bias voltage at 0.5 voltage. The current with and without sunlight irradiation was measured by a voltometer and the difference was ranged from 0.5 mA to 1 mA per cm2.

### Example 11

A solar collector was assembled using two pieces of ITO glass with a green particle layer sandwiched in the middle. The green particles (˜1 mg) were ground and suspended in butanol (0.5 mL). A slurry of the particles was applied onto one ITO glass surface using a plastic roller. Another ITO glass was then placed on the particle layer and two ITO glasses were adhered with tape on two sides, and the solvent was evaporated at room temperature overnight. Then the device was set up as displayed in FIG. 8 using a voltage meter to record the voltage or current. The two meter wires were connected to the device with conductive glue.

Measurement 1: The solar collector was placed inside of a building without direct sunlight or artificial light. After the meter stabilized in 10 minutes, the reading was 500 μW or 16.3 mV. Measurement 2: The solar collector was moved to a dark room illuminated only by a small nightlight. The meter reading dropped gradually and stabilized at 30 μW or 3.5 mV. It took about 4-5 hours to reach the equilibration. Measurement 3: The solar collector was moved outdoors and placed under direct sunlight. The meter reading immediately increased and stabilized (less than 1 minute) at 1350 μW or 30 mV. Measurement 4: the solar collector was moved to shaded area outside without direct sunlight radiation. The meter reading dropped gradually and stabilized (after about 30 minutes) at 850 μW or 21 mV.

The detailed description set forth above is provided to aid those skilled in the art in practicing the present invention. However, the invention described and claimed herein is not to be limited in scope by the specific embodiments herein disclosed because these embodiments are intended as illustrations only of several aspects of the invention. Any equivalent embodiments are intended to be within the scope of this invention. Indeed, various modifications of the invention in addition to those shown and described herein will become apparent to those skilled in the art from the foregoing description which do not depart from the spirit or scope of the present inventive discovery. Such modifications are also intended to fall within the scope of the appended claims.

### REFERENCES CITED

All publications, patents, patent applications and other references cited in this application are incorporated herein by reference in their entirety for all purposes to the same extent as if each individual publication, patent, patent application or other reference was specifically and individually indicated to be incorporated by reference in its entirety for all purposes. Citation of a reference herein shall not be construed as an admission that such is prior art to the present invention

What is claimed is:

1. A collector for solar or other light or heat energy conversion to electrical energy comprising a matrix of conductive material incorporating Europium-containing nanoparticles.

2. The collector of claim 1 wherein the nanoparticle comprises an aluminum oxide base crystal framework; the Eu is an activator; at least one energy reservoir selected from the group consisting of Mg, Ca, Sr and Ba; and at least one co-activator selected from the group consisting of Sc, Y, La, Ce, Pr, Nd, Sm, Gd, Tb, Dy, Ho, Er, Tm, Yb, Lu, and Bi.

3. The collector of claim 1 wherein the matrix of conductive material comprises one or more materials selected from the group consisting of glass, polymer, metal, alloy, ITO glass or other semi-conductive materials.

4. The collector of claim 3 wherein constituents of the conductive polymer are specifically chosen to provide optimal band gap values for transfer of photo-induced electrons excited in the Europium-containing nanoparticles.

5. The collector of claim 1 wherein one of more types of Europium-containing nanoparticles are co-polymerized into a conductive polymer.

6. The collector of claim 1 wherein one or more types of Europium-containing nanoparticles are incorporated into a semi-conductive ionic liquid.

7. The collector of claim 1 wherein there are one or more types of Europium-containing nanoparticles and the one or more types of Europium-containing nanoparticles are selected from the group consisting of green nanoparticles, purple nanoparticles, and combinations thereof.

8. The collector of claim 1 wherein the collector further comprises a carbon film backing to the matrix of conductive material incorporating Europium-containing nanoparticles.

9. The collector of claim 1 wherein there are one or more types of Europium-containing nanoparticles and the one or more types of Europium-containing nanoparticles are capable of absorbing radiation selected from the group consisting of infrared, visible, ultraviolet light, heat and any combination thereof for conversion to electrical energy.

10. The collector of claim 9 wherein the one or more types of nanoparticles are capable of absorbing IR, visible, UV and heat radiation.

11. The collector of claim 1 wherein there are one or more types of Europium-containing nanoparticles and the one or more types of nanoparticles are capable of conversions to electrical energy selected from the group consisting of up-conversion, down-conversion, heat conversion and any combination thereof.

12. The collector of claim 11 wherein the one or more types of nanoparticles are capable of up-conversion, down-conversion, and heat-conversion.

13. The collector of claim 1 wherein there are one or more types of Europium-containing nanoparticles and one or more of the types of nanoparticles incorporated are capable of absorbing wave-lengths which include wave-lengths in the range of from about 270 nm to about 500 nm and from about 800 nm to about 1050.

14. The collector of claim 13 wherein the one or more types of nanoparticles incorporated which are capable of absorbing wave-lengths which include wave-lengths in the range of from about 270 nm to about 500 nm and from about 800 nm to about 1050 have emission peaks at about 510 and about 540 nm.

15. The collector of claim 1 wherein there are one or more types of Europium-containing nanoparticles and one or more of the types of nanoparticles incorporated are capable of absorbing wave-lengths which include wave-lengths in the range of from about 250 nm to about 425 nm and from about 650 nm to about 800 nm.

16. The collector of claim 15 wherein the one or more types of nanoparticles incorporated are capable of absorbing wave-lengths which include wave-lengths in the range of from about 250 nm to about 425 nm and from about 650 nm to about 800 have an emission peak at about 440 nm.

17. The collector of claim 1 wherein there are one or more types of Europium-containing nanoparticles and the combination of types of nanoparticles incorporated are capable of absorbing wave-lengths anywhere in the electromagnetic spectrum ranging at least from about 250 nm to about 500 nm and at least from about 650 nm to about 1050 nm.

18. The collector of claim 1 wherein there are one or more types of Europium-containing nanoparticles and one or more of the types of nanoparticles incorporated are capable of being excited by heat within the range from at least 100 C to least about 800 C.

19. The collector of claim 1 wherein at least a portion of the nanoparticles are capable of producing an emission with an emission half-life of about one minute or longer.

20. The collector of claim 1 wherein at least a portion of the nanoparticles are capable of producing a radiation energy conversion rate of at least 15%.

21. The collector of claim 1 wherein the collector is rigid and planar.

22. The collector of claim 1 wherein the collector is flexible and capable of assuming differing orientations to facilitate storage or transport and energy collection.

23. A method for converting solar or other light or heat energy to electrical energy comprising exposing a collector to radiation for a time sufficient to convert solar or other light or heat energy to electrical energy, the collector comprising a matrix of conductive material incorporating Europium-containing nanoparticles.

24. A method as set forth in claim 23 wherein the energy produced is used to power vehicles or other transportation devices or satellites, space stations or other extraterrestrial devices or systems.

25. A method as set forth in claim 23 wherein the collector is incorporated into articles of clothing.

26. A method as set forth in claim 23 wherein the conversion to electrical energy occurs during time periods in which the exposure to radiation occurs solely under cloudy or rainy weather conditions.

27. A method as set forth in claims 23 wherein the collector is capable of withstanding repeated use without loss of function.

28. A method for storing electrical energy comprising exposing a collector as set forth in claim 1 to radiation for a time sufficient to convert solar, other light, or heat energy to electrical energy and retaining at least a portion of said converted energy for a subsequent time for which said energy is desired for use.
